(19) United States
(12) Patent Application Publication
(10) Pub. No.: US 2008/0242017 A1
(43) Pub. Date: Oct. 2, 2008

(54) METHOD OF MANUFACTURING SEMICONDUCTOR MOS TRANSISTOR DEVICES

(76) Inventors: Kun-Hsien Lee, Tai-Nan City (TW); Cheng-Tung Huang, Kao-Hsiung City (TW); Shyh-Fann Ting, Kao-Hsiung Hsien (TW); Li-Shian Jeng, Tai-Tung Hsien (TW); Wen-Han Hung, Kao-Hsiung City (TW); Tzyy-Ming Cheng, Hsin-Chu City (TW); Chia-Wen Liang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/690,863

(22) Filed: Mar. 26, 2007

(51) Int. Cl. H01L 21/44; H01L 21/336; H01L 21/8238

(52) U.S. Cl. 438/231; 438/682; 438/305

(57) ABSTRACT

A method of fabricating metal-oxide-semiconductor (MOS) transistor devices is disclosed. A semiconductor substrate is provided. A gate dielectric layer is formed. A gate electrode is stacked on the gate dielectric layer. The gate electrode has vertical sidewalls and a top surface. A liner is formed on the vertical sidewalls of the gate electrode. A silicon nitride spacer is formed on the liner. Using the gate electrode and the silicon nitride spacer as an implantation mask, a source/drain is implanted into the substrate. After the source/drain implant, the silicon nitride spacer is then stripped. A silicide layer is formed on the source/drain region. Subsequently, a silicon nitride cap layer is deposited. The silicon nitride cap layer has a specific stress status.

### BACKGROUND OF THE INVENTION

1. Field of the Invention

The present invention generally relates to the field of semiconductor transistor devices, and more particularly to a method of manufacturing semiconductor NMOS and PMOS transistor devices having improved saturation current and performance.

2. Description of the Prior Art

High-speed metal-oxide-semiconductor (MOS) transistor devices have been proposed in which a strained silicon (Si) layer, which has been grown epitaxially on a Si wafer with a silicon germanium (SiGe) layer disposed therebetween, is used for the channel area. In this type of strained Si-FET, a biaxial tensile strain occurs in the silicon layer due to the SiGe which has a larger lattice constant than Si, and as a result, the Si band structure alters, the degeneracy is lifted, and the carrier mobility increases. Consequently, using this strained Si layer for a channel area typically enables a 1.5 to 8-fold speed increase.

FIGS. 1-3 are schematic cross-sectional diagrams illustrating a prior art method of fabricating a semiconductor NMOS transistor device 10. As shown in FIG. 1, the conventional NMOS transistor device 10 generally includes a semiconductor substrate generally comprising a silicon layer 16 having a source 18 and a drain 20 separated by a channel region 22. The silicon layer 16 is typically a strained silicon layer formed by epitaxially growing a silicon layer on a SiGe layer (not shown). Ordinarily, the source 18 and drain 20 further border a shallow-junction source extension 17 and a shallow-junction drain extension 19, respectively. A thin oxide layer 14 separates a gate 12, generally comprising polysilicon, from the channel region 22.

In the device 10 illustrated in FIG. 1, the source 18 and drain 20 are N+ regions having been doped by arsenic, antimony or phosphorous. The channel region 22 is generally boron doped. A silicon nitride spacer 32 is formed on sidewalls of the gate 12. A liner 30, generally comprising silicon dioxide, is interposed between the gate 12 and the silicon nitride spacer 32. A salicide layer 42 is selectively formed on the exposed silicon surface of the device 10. Fabrication of an NMOS transistor such as the device 10 illustrated in FIG. 1 is well known in the art and will not be discussed in detail herein.

Referring to FIG. 2, after forming the NMOS transistor device 10, a silicon nitride cap layer 46 is typically deposited thereon. As shown in FIG. 2, the silicon nitride cap layer 46 covers the salicide layer 42 and the silicon nitride spacer 32. The thickness of the silicon nitride cap layer 46 is typically in the range of between 200 angstroms and 400 angstroms for subsequent etching stop purposes. A dielectric layer 48 such as silicon oxide or the like is deposited over the silicon nitride cap layer 46. The dielectric layer 48 is typically much thicker than the silicon nitride cap layer 46.

Referring to FIG. 3, subsequently, conventional lithographic and etching processes are carried out to form a contact hole 52 in the dielectric layer 48 and in the silicon nitride cap layer 46. As aforementioned, the silicon nitride cap layer 46 acts as an etching stop layer during the dry etching process to alleviate source/drain damages caused by the etchant substances.

However, prior art techniques involving the deposition of a graded SiGe layer underneath the silicon channel have several drawbacks. The SiGe layer tends to introduce defects, sometimes called threading dislocations, in the silicon, which can impact yields significantly. Also, the graded SiGe layer is deposited across the wafer, making it harder to optimize the NMOS and PMOS transistors separately. And the silicon germanium layer has poor thermal conductivity. Another concern with the conventional approach is that some dopants diffuse more rapidly through the SiGe layer, resulting in a non-optimium diffusion profile in the source/drain regions.

Thus, a need exists in this industry to provide an inexpensive method for making a MOS transistor device having improved functionality and performance.

### SUMMARY OF THE INVENTION

It is the primary object of the present invention to provide a method of manufacturing a silicon nitride spacer-less semiconductor MOS transistor devices having improved performance.

According to the claimed invention, a method of manufacturing a metal-oxide-semiconductor (MOS) transistor device is disclosed. A semiconductor substrate is provided. A gate dielectric layer is formed on the semiconductor substrate. A gate electrode is formed on the gate dielectric layer. The gate electrode has vertical sidewalls and a top surface. A liner is formed on the vertical sidewalls of the gate electrode. A silicon nitride spacer is formed on the liner. Using the gate electrode and the silicon nitride spacer as an implantation mask, the semiconductor substrate is ion implanted thereby forming a source/drain region of the MOS transistor device. The silicon nitride spacer is removed. After removing the silicon nitride spacer, a silicide layer is formed on the source/drain region.

From one aspect of this invention, a method of manufacturing a metal-oxide-semiconductor (MOS) transistor device is disclosed. A semiconductor substrate is provided. A gate dielectric layer is formed on the semiconductor substrate. A gate electrode is formed on the gate dielectric layer, wherein the gate electrode has vertical sidewalls and a top surface. A liner is formed on the vertical sidewalls of the gate electrode. A silicon nitride layer is deposited on the liner. The silicon nitride layer and the liner is dry etched back, and the semiconductor substrate is recessed, thereby forming silicon nitride spacer on the vertical sidewalls of the gate electrode and a recessed area next to the silicon nitride spacer. The recessed area is re-filled with a semiconductor material layer. Using the gate electrode and the silicon nitride spacer as an implantation mask, the semiconductor substrate is ion implanted thereby forming a source/drain region of the MOS transistor device. The silicon nitride spacer is removed. After removing the silicon nitride spacer, a silicide layer is formed on the source/drain region.

From another aspect of this invention, a method of manufacturing a complementary metal-oxide-semiconductor (CMOS) transistor device is disclosed. A semiconductor substrate is provided. The semiconductor substrate has thereon an NMOS region and a PMOS region. First and second gate electrodes are formed in the NMOS region and PMOS region respectively. A liner is formed on the sidewalls of the first and second gate electrodes. A silicon nitride spacer is formed on the liner. N type dopants and P type dopants are ion implanted into the semiconductor substrate in the NMOS region and PMOS region respectively, thereby forming a source/drain region. The silicon nitride spacer is removed. After removing the silicon nitride spacer, a silicide layer is formed on the source/drain region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-3 are schematic cross-sectional diagrams illustrating a prior art method of fabricating a semiconductor NMOS transistor device;

FIGS. 4-8 are schematic cross-sectional diagrams illustrating a method of fabricating semiconductor MOS transistor devices in accordance with a first preferred embodiment of the present invention;

FIGS. 9-14 are schematic cross-sectional diagrams illustrating a method of fabricating semiconductor CMOS transistor devices in accordance with a second preferred embodiment of the present invention; and

FIGS. 15-20 are schematic cross-sectional diagrams illustrating a method of fabricating semiconductor MOS transistor devices in accordance with a third preferred embodiment of the present invention.

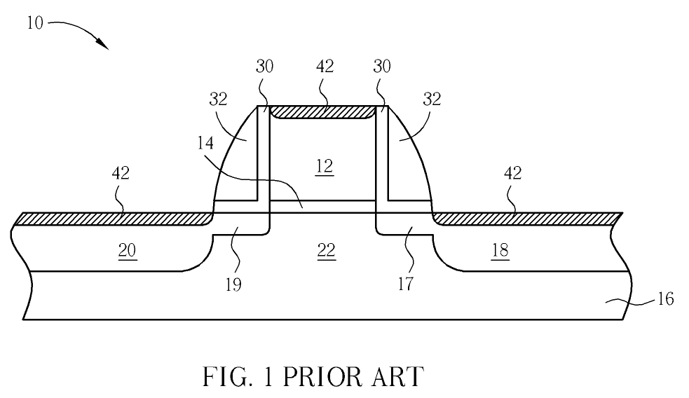

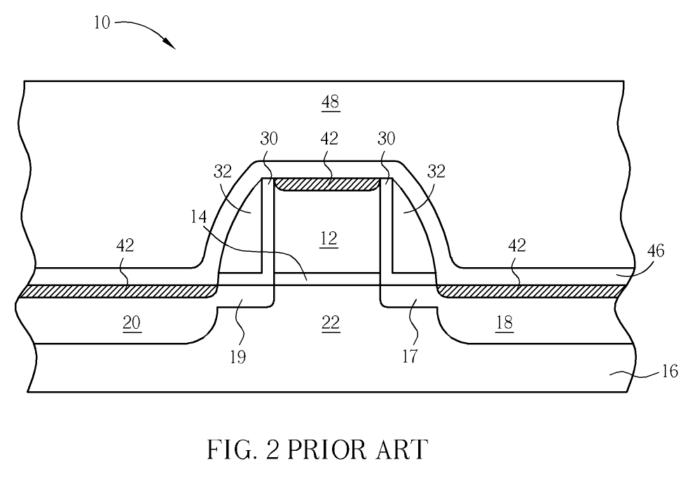

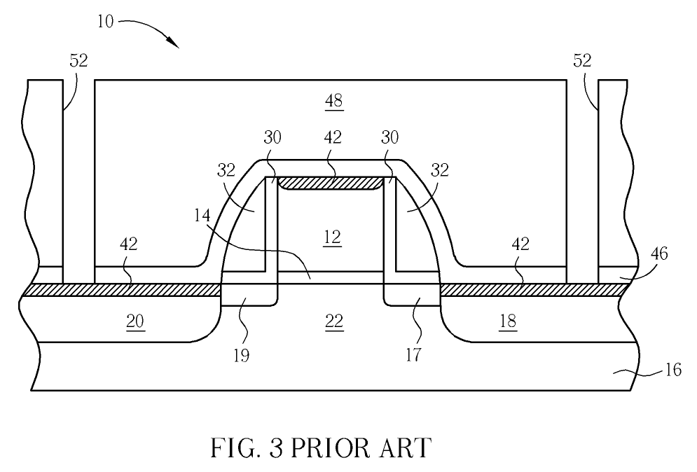

### DETAILED DESCRIPTION

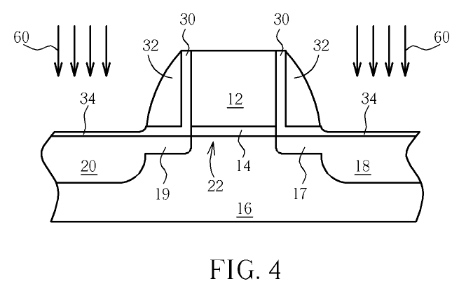

Please refer to FIGS. 4-8. FIGS. 4-8 are schematic cross-sectional diagrams illustrating a method of fabricating semiconductor MOS transistor devices in accordance with a first preferred embodiment of the present invention, wherein like number numerals designate similar or the same parts, regions or elements. It is to be understood that the drawings are not drawn to scale and are served only for illustration purposes. It is to be understood that some lithographic and etching processes relating to the present invention method are known in the art and thus not explicitly shown in the drawings.

The present invention pertains to a method of fabricating MOS transistor devices or CMOS devices of integrated circuits. A method for fabricating a MOS device is demonstrated through FIGS. 4-8, which is applicable to both NMOS and PMOS processes.

As shown in FIG. 4, a semiconductor substrate generally comprising a silicon layer 16 is prepared. According to this invention, the semiconductor substrate may be a silicon substrate or a silicon-on-insulator (SOI) substrate, but not limited thereto. Preferably, the semiconductor substrate is silicon based, (e.g., silicon, silicon alloy or a combination thereof including Si, SiGe, SiC, SiGeC) although any suitable semiconductor material may be used including, but not limited to GaAs, InAs, InP or other III/V compound semiconductors. The semiconductor substrate may also include a multilayer structure in which at least the top layer thereof is a semiconductor.

The method for forming the intermediate MOS structure depicted in FIG. 4 generally comprises forming shallow trench isolation (STI) structure in the silicon layer 16; forming gate dielectric layer 14; forming gate 12; forming liner 30; ion implanting shallow junction source/drain extensions 17 and 19; and forming nitride spacer 32. The source extension 17 and drain extension 19 are separated by channel 22. The gate 12 may comprise polysilicon or metals. The gate dielectric layer 14 may include oxynitride-nitride stack, pure nitride, high-k oxide or oxynitride or respective silicate such as Al₂O₃, HfO₂, ZrO₂, HfOₓN_{y}, HfSiₓO_{y}N_{z}.

The method of forming the nitride spacer 32 generally includes the steps of depositing a conformal silicon nitride layer (not shown) on the silicon oxide liner 30; etching back the silicon nitride layer to form the nitride spacer 32 on sidewalls of the gate 12. According the preferred embodiment of this invention, the thickness of the nitride space is between 300-600 angstroms.

Subsequently, a source/drain ion implantation process 60 is carried out to implant dopants into the silicon layer 16 adjacent to the nitride spacer 32, thereby forming source region 18 and drain region 20. It should be noted that the etching of the nitride spacer 32 stops on the silicon oxide liner 30. Therefore, a thin oxide layer 34 of about 30-40 angstroms remains on the source region 18 and drain region 20.

The nitride spacer 32 may be replaced with other suitable materials including, but not limited to, silicon oxy-nitride (SiON) or silicon carbide (SiC).

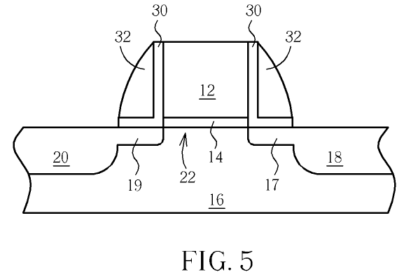

As shown in FIG. 5, after the source/drain ion implantation process, an etching process such as wet etching or dry etching is performed to remove the thin oxide layer 34 from the surfaces of the source region 18 and the drain region 20. For example, the thin oxide layer 34 may be removed by using diluted hydrofluoric acid solution.

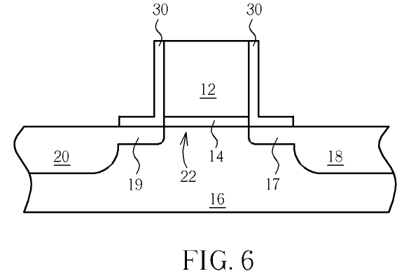

As shown in FIG. 6, after removing the thin oxide layer 34 on the source/drain region, another etching process such as wet etching, dry etching or vapor-etching method is carried out to completely remove the nitride spacer 32 from the sidewalls of the gate 12, leaving the silicon oxide liner 30 substantially intact. For example, the nitride spacer 32 may be removed by using hot phosphoric acid solution. The liners 30 has an L-shaped cross-section, and preferably has a thickness of about 30˜120 angstroms.

In another case, the nitride spacer 32 may be removed by using dry etching methods. For example, the nitride spacer 32 can be removed by using a gas mixture comprising hydrogen fluoride vapor and oxidizing agent such as HNO₃, O₃, H₂O₂, HClO, HNO₂, O₂, H₂SO₄, Co₂, or Br₂ at properly controlled process temperatures. In still another case, the nitride spacer 32 may be removed by using anhydrous hydrogen halogenide such as HF or HCl gas.

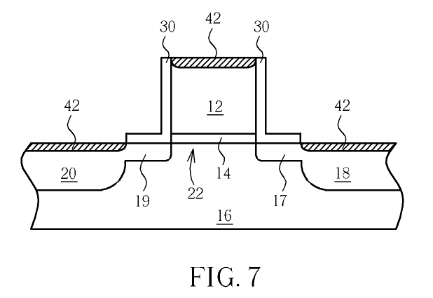

As shown in FIG. 7, after removing the nitride spacer 32, a conventional silicidation or salicidation process is carried out to form a silicide layer or salicide layer 42 such as NiSi, CoSi, TiSi, PtSi, PdSi or MoSi on the source region, the drain region and on the gate. It is one important feature of this invention that the gate has no nitride spacer on its sidewalls, and the silicidation or salicidation process is performed after the nitride spacer 32 is removed. By doing this, the silicide layer or salicide layer 42 on the source and drain will not be damaged by the etchant used to etch the nitride spacer 32.

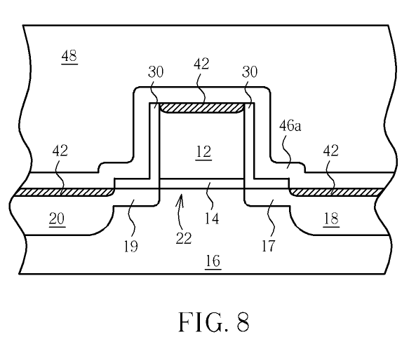

As shown in FIG. 8, a conformal silicon nitride cap layer 46a is deposited on the substrate. Preferably, the silicon nitride cap layer 46 has a thickness of about 30˜2000 angstroms, for example, about 1000 angstroms. Because the nitride spacer 32 is removed, the silicon nitride cap layer 46a thus directly borders the liner 30 on the sidewalls of the gate 12 and is closer to the channel 22 than that of the prior art MOS device. According to the preferred embodiment, the silicon nitride cap layer 46a is initially deposited in a pre-selected stress status: compressive-stress (ex. −0.1 Gpa˜−3 Gpa) for PMOS and tensile-stress (ex. 0.1 Gpa˜−3 Gpa) for NMOS.

Subsequently, a dielectric layer 48 is deposited on the silicon nitride cap layer 46a. The dielectric layer 48 may be made of silicon oxide, doped silicon oxide or other suitable materials such as low-k materials. According to another embodiment of this invention, the dielectric layer 48 is stressed. For example, the dielectric layer 48 is tensile-stressed or compressively stressed. The silicon nitride cap layer 46a also acts as an etching stop layer during subsequent dry etching of the contact holes for alleviating surface damages caused by the etchant substances.

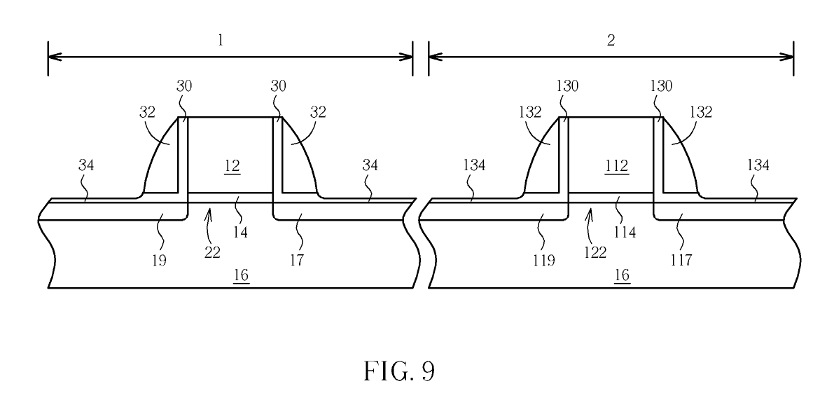

A CMOS process in accordance with a second preferred embodiment is now demonstrated through FIGS. 9-14. As shown in FIG. 9, a semiconductor substrate generally comprising thereon a silicon layer 16 is prepared, wherein region 1 thereof is used to fabricate an NMOS device, while region 2 is used to fabricate a PMOS device. The semiconductor substrate may be a silicon substrate or a silicon-on-insulator (SOI) substrate, but not limited thereto. Preferably, the semiconductor substrate is silicon based, (e.g., silicon a silicon alloy or a combination thereof including Si, SiGe, SiC, SiGeC) although any suitable semiconductor material may be used including, but not limited to GaAs, InAs, InP or other III/V compound semiconductors.

The semiconductor substrate may also include a multilayer structure in which at least the top layer thereof is a semiconductor. The method for forming the intermediate MOS structure depicted in FIG. 9 generally comprises forming shallow trench isolation (STI) structure in the silicon layer 16; forming gate dielectric layers 14 and 114; forming gates 12 and 112; forming liners 30 and 130; ion implanting shallow junction source/drain extensions; and forming spacers 32 and 132.

Using suitable implant masks, shallow-junction source extension 17 and shallow-junction drain extension 19 are formed in the silicon layer 16 within the region 1. The source extension 17 and drain extension 19 are separated by N channel 22. In region 2, likewise, shallow-junction source extension 117 and shallow-junction drain extension 119 are formed in the silicon layer 16 and are separated by P channel 122.

The gate dielectric 14 or 114 is formed on the surface of a semiconductor material using a suitable formation step such as for example, depositing the dielectric, a thermal oxidation, nitridation or oxynitridation. Combinations of the aforementioned processes may also be used in forming the gate dielectric. The gate dielectric is an insulating material including an oxide, nitride, oxynitride or any combination thereof. A highly preferred insulating material that may be employed in the present invention as the gate dielectric is nitrided SiO₂ or oxynitride.

Although it is preferred to use nitrided SiO₂ or oxynitride as the gate dielectric material, the present invention also contemplates using insulating materials, i.e., dielectrics, which have a higher dielectric constant, k, than nitrided SiO₂. For example, the gate dielectric may include oxynitride-nitride stack, pure nitride, high-k oxide or oxynitride or respective silicate such as Al₂O₃, HfO₂, ZrO₂, HfOₓN_{y}, HfSiₓO_{y}N_{z}.

Preferably, the gate 12 or 112 is made of doped polysilicon. However, the gate is any suitable conductive material such as an alloy of doped silicon, such as silicon-germanium (SiGeₓ) or silicon-carbon (SiCₓ) and/or other conductive materials including elemental metals (W, Ta, Mo, Ti, Re, Ir, Al, etc.), metal silicides (CoSiₓ, NiSiₓ, WSiₓ, TiSiₓ), metal nitrides (WN, TaN, TiN, TaSiN) and its alloys. The gate material can be in either crystalline, polycrystalline, or amorphous form and may include multiple layers of various conducting materials.

Silicon nitride spacers 32 and 132 are formed on respective sidewalls of the gates 12 and 112. Liners 30 and 130 such as silicon dioxide are interposed between the silicon nitride spacer and the gate. The liners 30 and 130 are typically L shaped and have a thickness of about 30˜120 angstroms. The liners 30 and 130 may further comprise an offset spacer that is known in the art and is thus omitted in the figures.

The method of forming the nitride spacers 32 and 132 generally includes the steps of depositing a conformal silicon nitride layer (not shown) on the silicon oxide liner; dry etching back the silicon nitride layer to form the nitride spacer on sidewalls of the gate. According the preferred embodiment of this invention, the thickness of the nitride space is between 300-600 angstroms. As previously mentioned, the etching of the nitride spacer stops on the silicon oxide liner. Therefore, a thin oxide layers 34 and 134 of about 30-40 angstroms remains on the source region and drain region.

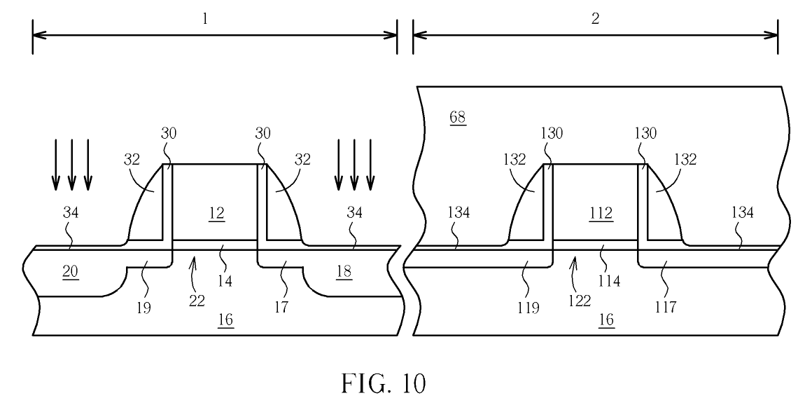

As shown in FIG. 10, after forming the silicon nitride spacers 32 and 132, a mask layer 68 such as a photo resist layer is formed to mask the region 2 only. An ion implantation process is then carried out to dope N type dopant species such as arsenic, antimony or phosphorous into the silicon layer 16, thereby forming heavily doped source region 18 and heavily doped drain region 20. The mask layer 68 is then stripped off.

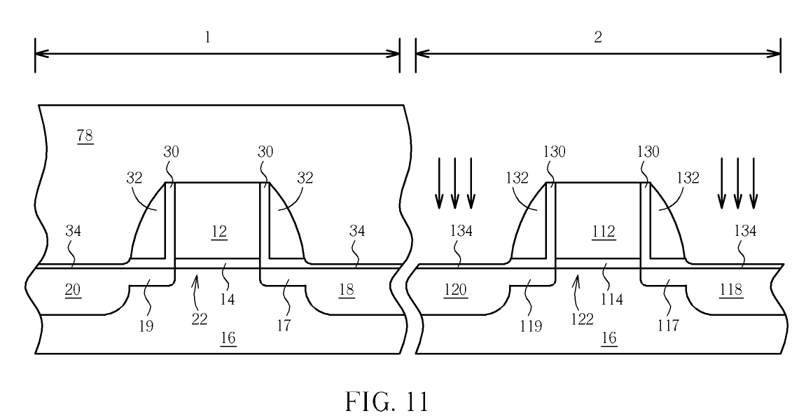

As shown in FIG. 11, a mask layer 78 such as a photo resist layer is formed to mask the region 1 only. An ion implantation process is carried out to dope P type dopant species such as boron into the silicon layer 16, thereby forming source region 118 and drain region 120. The mask layer 78 is then stripped off using methods known in the art.

It is to be understood that the sequence as set forth in FIGS. 10 and 11 may be converse. That is, the P type doping for the region 2 may be carried out first, then the N type doping for the region 1. After the source/drain doping, the substrate may be subjected to an annealing and/or activation thermal process that is known in the art.

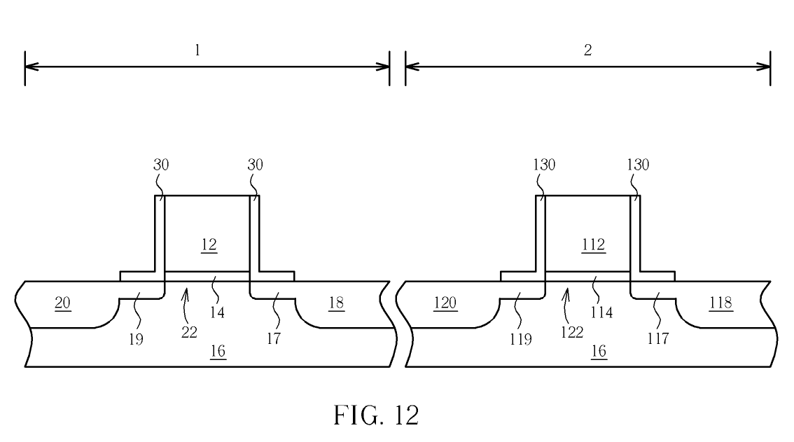

As shown in FIG. 12, after the source/drain ion implantation process, an etching process such as wet etching or dry etching is performed to remove the thin oxide layers 34 and 134 from the surfaces of the source region and the drain region. For example, the thin oxide layers 34 and 134 may be removed by using diluted hydrofluoric acid solution.

After removing the thin oxide layers 34 and 134 on the source/drain region, another etching process such as wet etching, dry etching or vapor-etching method is carried out to completely remove the nitride spacers 32 and 132 from the sidewalls of the gates 12 and 112, respectively, leaving the silicon oxide liners 30 and 130 substantially intact. For example, the nitride spacer may be removed by using hot phosphoric acid solution. The remaining oxide liners has an L-shaped cross-section, and preferably has a thickness of about 30˜120 angstroms.

In another case, the nitride spacers 32 and 132 may be removed by using dry etching methods. For example, the nitride spacer can be removed by using a gas mixture comprising hydrogen fluoride vapor and oxidizing agent such as HNO₃, O₃, H₂O₂, HClO, HNO₂, O₂, H₂SO₄, Cl₂, or Br₂ at properly controlled process temperatures. In still another case, the nitride spacer may be removed by using anhydrous hydrogen halogenide such as HF or HCl gas.

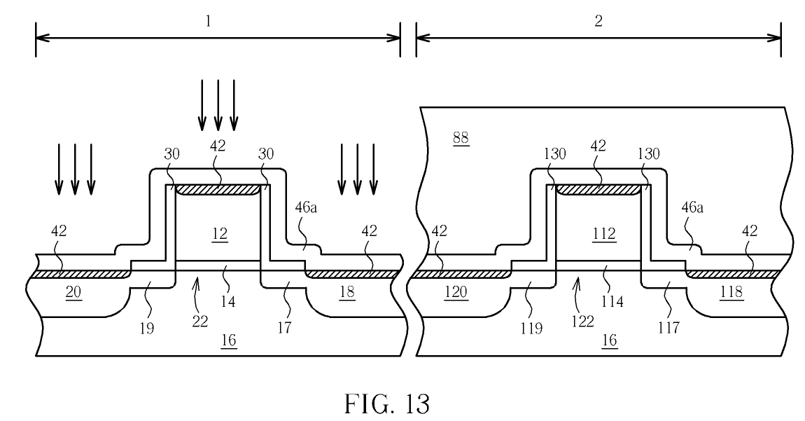

As shown in FIG. 13, a conventional salicide process is performed to form a salicide layer 42a such as NiSi, CoSi, TiSi, PtSi, PdSi or MoSi layer atop the gates 12 and 122, on the exposed source regions 18 and 118 and also on the exposed drain regions 20 and 120. The salicide process is well known in the art. For example, the salicide process typically comprises blanket sputtering or depositing a metal layer such as cobalt or nickel over the substrate; reacting the metal layer with the silicon surfaces to form silicide; and removing un-reacted metal layer.

After removing the silicon nitride spacers, approximately L shaped liners are left. However, this invention is not limited to an L shaped liner. It is to be understood that a mild etching process may be carried out to slightly etch the liner, thereby shrinking its thickness. In another case, the liner may be etched away. In general, the liners 30 and 130 have a thickness of about 0 to 500 angstroms.

A conformal silicon nitride cap layer 46a is deposited on the substrate. Preferably, the silicon nitride cap layer 46a has a thickness of about 30˜2000 angstroms, for example, about 1000 angstroms. The silicon nitride cap layer 46a directly borders the liners 30 and 130 on the sidewalls of the gates 12 and 122 of the NMOS transistor device and the PMOS transistor device, respectively. According to the second preferred embodiment, the silicon nitride cap layer 46a is initially deposited in a first stress status such as a compressive-stressed status (ex. −0.1 Gpa˜−3 Gpa). Thereafter, the silicon nitride cap layer 46a in the region 2 is covered with a mask layer 88.

The stress of the exposed silicon nitride cap layer 46a within the region 1 is altered to a second stress status that is opposite to the first stress status, i.e., a tensile-stressed status (ex. 0.1 Gpa˜−3 Gpa) in this case. By doing this, the channel region 22 is tensile-stressed by the silicon nitride cap layer 46a, while the channel region 122 is compressively stressed by the silicon nitride cap layer 46a, both in the channel direction.

According to the preferred embodiment, the alteration of the stress status of the exposed silicon nitride cap layer 46a within the region 1 is accomplished by using a germanium ion implantation. However, it is to be understood that the alteration of the stress status of the exposed silicon nitride cap layer 46a within the region 1 may be accomplished by using other methods known to those skilled in the art.

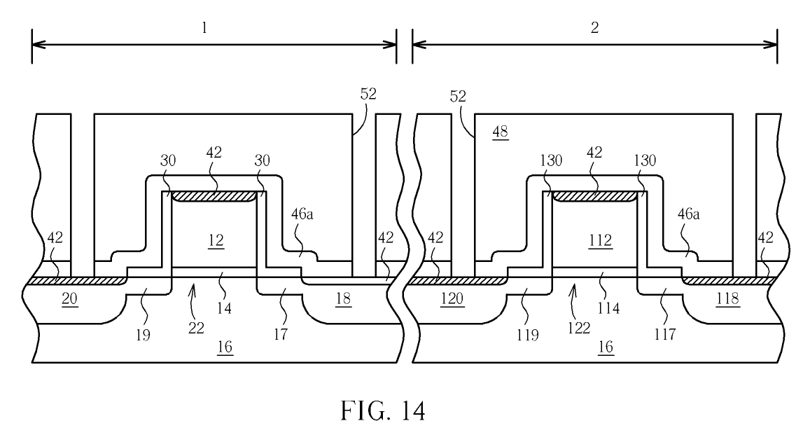

As shown in FIG. 14, subsequently, a dielectric layer 48 is deposited over the regions 1 and 2 on the silicon nitride cap layer 46a. The dielectric layer 48 may be made of silicon oxide, doped silicon oxide or other suitable materials such as low-k materials. According to another embodiment of this invention, the dielectric layer 48 is stressed. For example, the dielectric layer 48 within region 1 is tensile-stressed, while the dielectric layer 48 within region 2 is compressively stressed.

Thereafter, conventional lithographic and etching processes are carried out to form contact holes 52 in the dielectric layer 48 and in the silicon nitride cap layer 46a. The contact holes 52 communicate with the source/drain regions of the devices. In another case, a contact hole may be formed to communicate with the gate electrode. From one aspect of the present invention, the silicon nitride cap layer 46a acts as an etching stop layer during the dry etching of the contact holes 52 for alleviating surface damages caused by the etchant substances.

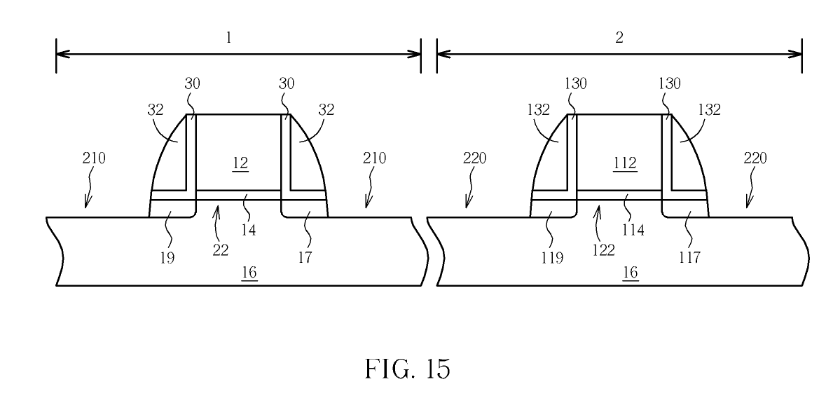

A CMOS process in accordance with a third preferred embodiment is now demonstrated through FIGS. 15-20. As shown in FIG. 15, a semiconductor substrate generally comprising thereon a silicon layer 16 is prepared, wherein region 1 thereof is used to fabricate an NMOS device, while region 2 is used to fabricate a PMOS device. The semiconductor substrate may be a silicon substrate or a silicon-on-insulator (SOI) substrate, but not limited thereto. Preferably, the semiconductor substrate is silicon based, (e.g., silicon a silicon alloy or a combination thereof including Si, SiGe, SiC, SiGeC) although any suitable semiconductor material may be used including, but not limited to GaAs, InAs, InP or other III/V compound semiconductors.

The semiconductor substrate may also include a multilayer structure in which at least the top layer thereof is a semiconductor. The method for forming the intermediate MOS structure depicted in FIG. 9 generally comprises forming shallow trench isolation (STI) structure in the silicon layer 16; forming gate dielectric layers 14 and 114; forming gates 12 and 112; forming liners 30 and 130; ion implanting shallow junction source/drain extensions; and forming spacers 32 and 132.

Using suitable implant masks, shallow-junction source extension 17 and shallow-junction drain extension 19 are formed in the silicon layer 16 within the region 1. The source extension 17 and drain extension 19 are separated by N channel 22. In region 2, likewise, shallow-junction source extension 117 and shallow-junction drain extension 119 are formed in the silicon layer 16 and are separated by P channel 122.

The gate dielectric 14 or 114 is formed on the surface of a semiconductor material using a suitable formation step such as for example, depositing the dielectric, a thermal oxidation, nitridation or oxynitridation. Combinations of the aforementioned processes may also be used in forming the gate dielectric. The gate dielectric is an insulating material including an oxide, nitride, oxynitride or any combination thereof. A highly preferred insulating material that may be employed in the present invention as the gate dielectric is nitrided SiO₂ or oxynitride.

Although it is preferred to use nitrided SiO₂ or oxynitride as the gate dielectric material, the present invention also contemplates using insulating materials, i.e., dielectrics, which have a higher dielectric constant, k, than nitrided SiO₂. For example, the gate dielectric may include a oxynitride-nitride stack, a pure nitride, a high-k oxide or oxynitride or respective silicate such as Al₂O₃, HfO₂, ZrO₂, HfOₓN_{y}, HfSiₓO_{y}N_{z}.

Preferably, the gate 12 or 112 is made of doped polysilicon. However, the gate is any suitable conductive material such as an alloy of doped silicon, such as silicon-germanium (SiGeₓ) or silicon-carbon (SiCₓ) and/or other conductive materials including elemental metals (W, Ta, Mo, Ti, Re, Ir, Al, etc.), metal silicides (CoSiₓ, NiSiₓ, WSiₓ, TiSiₓ), metal nitrides (WN, TaN, TiN, TaSiN) and its alloys. The gate material can be in either crystalline, polycrystalline, or amorphous form and may include multiple layers of various conducting materials.

The method of forming the nitride spacers 32 and 132 generally includes the steps of depositing a conformal silicon nitride layer (not shown) on the silicon oxide liner; dry etching back the silicon nitride layer and the silicon oxide liner 30 and recessing the silicon layer 16 to a pre-selected depth such as 20˜300 angstroms, to form the nitride spacer on sidewalls of the gate and recessed area 210 and 220 next to the nitride spacers 32 and 132 respectively.

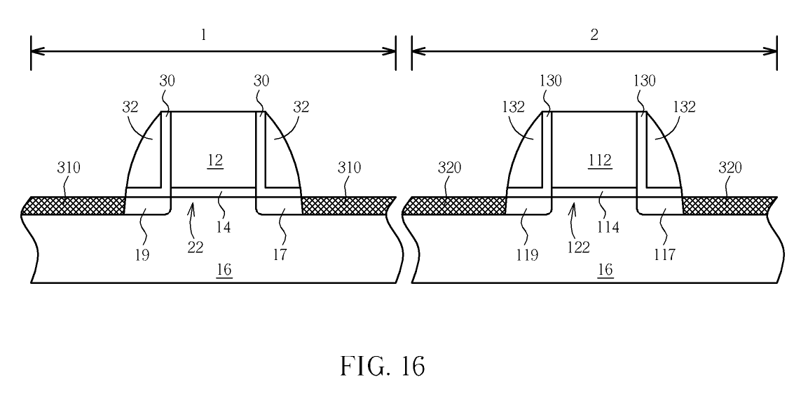

As shown in FIG. 16, a refill process is performed. The recessed areas 210 and 220 are re-filled with semiconductor material layers. For example, the recessed area 210 of region 1 is re-filled with silicon carbide layer 310 while the recessed area 220 of region 2 is refilled with SiGe 320.

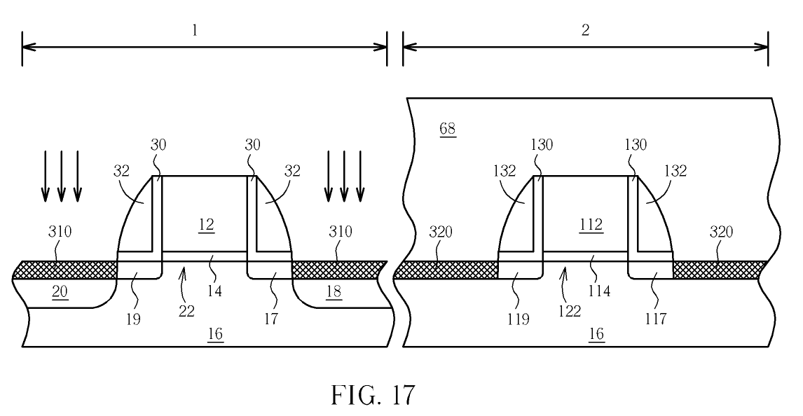

As shown in FIG. 17, a mask layer 68 such as a photo resist layer is formed to mask the region 2 only. An ion implantation process is then carried out to dope N type dopant species such as arsenic, antimony or phosphorous into the silicon layer 16, thereby forming heavily doped source region 18 and heavily doped drain region 20. The mask layer 68 is then stripped off.

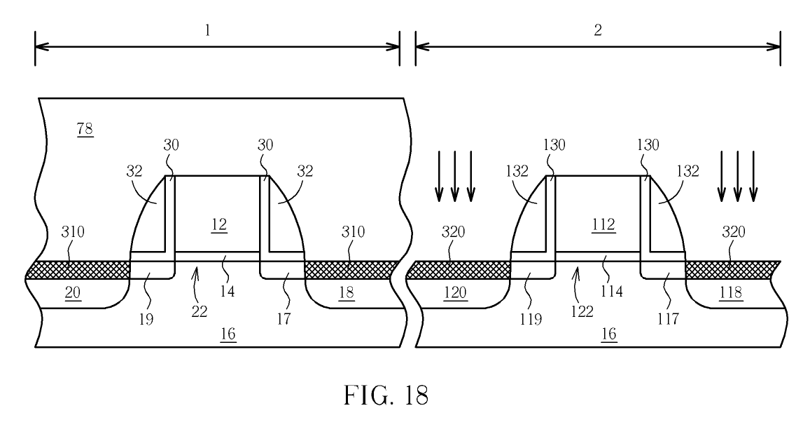

As shown in FIG. 18, a mask layer 78 such as a photo resist layer is formed to mask the region 1 only. An ion implantation process is carried out to dope P type dopant species such as boron into the silicon layer 16, thereby forming source region 118 and drain region 120. The mask layer 78 is then stripped off using methods known in the art.

It is to be understood that the sequence as set forth in FIGS. 17 and 18 may be converse. That is, the P type doping for the region 2 may be carried out first, then the N type doping for the region 1. After the source/drain doping, the substrate may be subjected to an annealing and/or activation thermal process that is known in the art.

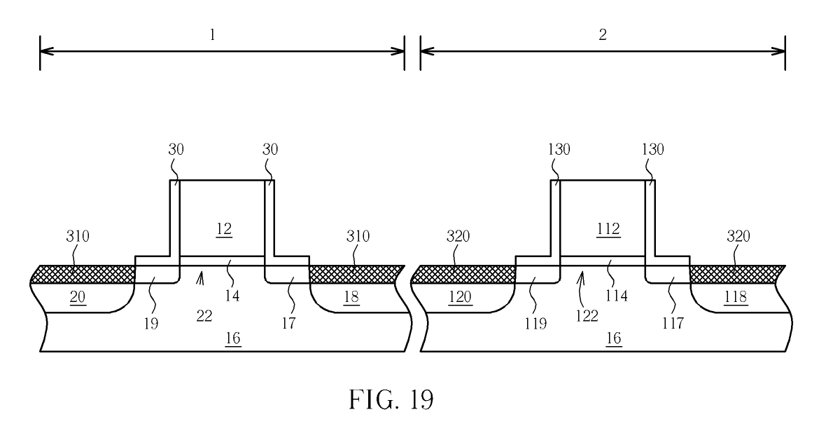

As shown in FIG. 19, after the source/drain ion implantation process, an etching process such as wet etching or dry etching is performed to remove the thin oxide layers 34 and 134 from the surfaces of the source region and the drain region. For example, the thin oxide layers 34 and 134 may be removed by using diluted hydrofluoric acid solution.

After removing the thin oxide layers 34 and 134 on the source/drain region, another etching process such as wet etching, dry etching or vapor-etching method is carried out to completely remove the nitride spacers 32 and 132 from the sidewalls of the gates 12 and 112, respectively, leaving the silicon oxide liners 30 and 130 substantially intact. For example, the nitride spacer may be removed by using hot phosphoric acid solution. The remaining oxide liners has an L-shaped cross-section, and preferably has a thickness of about 30˜120 angstroms.

In another case, the nitride spacers 32 and 132 may be removed by using dry etching methods. For example, the nitride spacer can be removed by using a gas mixture comprising hydrogen fluoride vapor and oxidizing agent such as HNO₃, O₃, H₂O₂, HClO, HNO₂, O₂, H₂SO₄, Cl₂, or Br₂ at properly controlled process temperatures. In still another case, the nitride spacer may be removed by using anhydrous hydrogen halogenide such as HF or HCl gas.

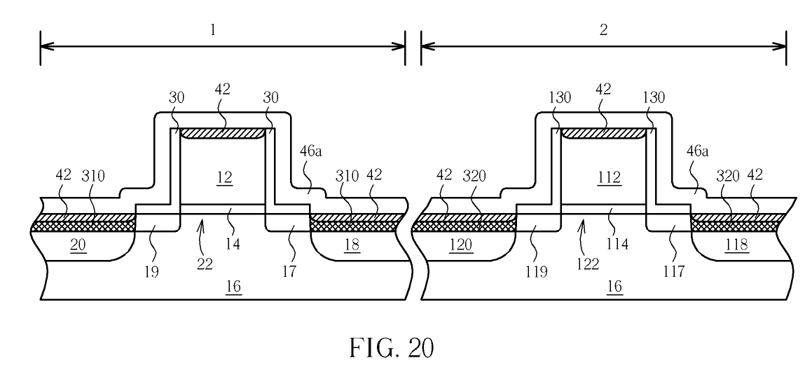

As shown in FIG. 20, a conventional salicide process is performed to form a salicide layer 42a such as NiSi, CoSi, TiSi, PtSi, PdSi or MoSi layer atop the gates 12 and 122, on the exposed source regions 18 and 118 and also on the exposed drain regions 20 and 120.

A conformal silicon nitride cap layer 46a is deposited on the substrate. Preferably, the silicon nitride cap layer 46a has a thickness of about 30˜2000 angstroms, for example, about 1000 angstroms. The silicon nitride cap layer 46a directly borders the liners 30 and 130 on the sidewalls of the gates 12 and 122 of the NMOS transistor device and the PMOS transistor device, respectively. According to the second preferred embodiment, the silicon nitride cap layer 46a is initially deposited in a first stress status such as a compressive-stressed status (ex. −0.1 Gpa˜−3 Gpa).

The stress of the exposed silicon nitride cap layer 46a within the region 1 is altered to a second stress status that is opposite to the first stress status, i.e., a tensile-stressed status (ex. 0.1 Gpa˜−3 Gpa) in this case. By doing this, the channel region 22 is tensile-stressed by the silicon nitride cap layer 46a, while the channel region 122 is compressively stressed by the silicon nitride cap layer 46a, both in the channel direction.

According to the preferred embodiment, the alteration of the stress status of the exposed silicon nitride cap layer 46a within the region 1 is accomplished by using a germanium ion implantation. However, it is to be understood that the alteration of the stress status of the exposed silicon nitride cap layer 46a within the region 1 may be accomplished by using other methods known to those skilled in the art.

It is advantageous to use the present invention method because the NMOS transistor is capped with a tensile-stressed silicon nitride cap layer and the PMOS transistor device is capped with a compressive-stressed silicon nitride cap layer. Since the silicon nitride spacers are removed, the stressed silicon nitride cap layer is therefore disposed more closer to the channels 22 and 122 of the devices 10 and 100, respectively, resulting in improved performance in terms of increased saturation current.

It is one important feature of this invention that the gate has no nitride spacer on its sidewalls, and the silicidation or salicidation process is performed after the nitride spacer is removed. By doing this, the silicide layer or salicide layer on the source and drain will not be damaged by the etchant used to etch the nitride spacer.

Those skilled in the art will readily observe that numerous modifications and alterations of the device and method may be made while retaining the teachings of the invention. Accordingly, the above disclosure should be construed as limited only by the metes and bounds of the appended claims.

1. A method of manufacturing a metal-oxide-semiconductor (MOS) transistor device, comprising:
providing a semiconductor substrate;
forming a gate dielectric layer on the semiconductor substrate;
forming a gate electrode on the gate dielectric layer, wherein the gate electrode has vertical sidewalls and a top surface;
forming a liner on the vertical sidewalls of the gate electrode;
forming a silicon nitride spacer on the liner;
ion implanting the semiconductor substrate using the gate electrode and the silicon nitride spacer as an implantation mask, thereby forming a source/drain region of the MOS transistor device;
removing the silicon nitride spacer;
after removing the silicon nitride spacer, forming a silicide layer on the source/drain region; and
after forming the silicide layer on the source/drain region, depositing a cap layer on the liner and on the silicide layer, wherein the cap layer directly borders the liner and has a pre-selected stress.

2. The method of manufacturing a MOS transistor device according to claim 1 wherein after ion implanting the semiconductor substrate and before removing the silicon nitride spacer, the method further comprises the following step:
performing an etching process to remove an oxide layer from surface of the source/drain region.

3. (canceled)

4. The method of manufacturing a MOS transistor device according to claim 3 wherein the cap layer has a thickness of about 30˜2000 angstroms.

5. The method of manufacturing a MOS transistor device according to claim 3 wherein the cap layer acts as a contact etch stop layer when etching a contact hole.

6. The method of manufacturing a MOS transistor device according to claim 3 wherein the pre-selected stress is tensile stress when the MOS transistor device is NMOS.

7. The method of manufacturing a MOS transistor device according to claim 3 wherein the pre-selected stress is compressive stress when the MOS transistor device is PMOS.

8. The method of manufacturing a MOS transistor device according to claim 3 wherein the cap layer comprises silicon nitride.

9. The method of manufacturing a MOS transistor device according to claim 1 wherein the liner comprises silicon oxide.

10. The method of manufacturing a MOS transistor device according to claim 1 further comprising a step of annealing the source/drain region.

11. The method of manufacturing a MOS transistor device according to claim 1 wherein the silicide layer comprises CoSi, NiSi, TiSi, PtSi, PdSi or MoSi.

12. The method of manufacturing a MOS transistor device according to claim 1 wherein the gate electrode comprises polysilicon or metals.

13. The method of manufacturing a MOS transistor device according to claim 1 wherein before removing the silicon nitride spacer, the method further comprises the following steps:
recessing the semiconductor substrate to a pre-selected depth to form a recessed area next to the silicon nitride spacer; and
re-filling the recessed area with a semiconductor epitaxial layer.

14. The method of manufacturing a MOS transistor device according to claim 13 wherein the MOS transistor device is NMOS and the semiconductor epitaxial layer is epitaxial silicon carbide.

15. The method of manufacturing a MOS transistor device according to claim 13 wherein the MOS transistor device is PMOS and the semiconductor epitaxial layer is epitaxial silicon germanium.

16. The method of manufacturing a MOS transistor device according to claim 1 wherein the silicon nitride spacer is removed by wet etching method, dry etching method or vapor-etching method.

17. The method of manufacturing a MOS transistor device according to claim 16 wherein the wet etching method comprises using phosphoric acid solution.

18. The method of manufacturing a MOS transistor device according to claim 16 wherein the dry etching method comprises using a gas mixture comprising hydrogen fluoride vapor and oxidizing agent.

19. The method of manufacturing a MOS transistor device according to claim 18 wherein the oxidizing agent comprises HNO₃, O₃, H₂O₂, HClO, HNO₂, O₂, H₂SO₄, Cl₂, or Br₂.

20. The method of manufacturing a MOS transistor device according to claim 16 wherein the vapor-etching method comprises using anhydrous hydrogen halogenide comprising HF or HCl gas.

21. The method of manufacturing a MOS transistor device according to claim 1 wherein after the formation of the silicon nitride spacer, the method further comprises forming an epitaxial silicon layer next to the silicon nitride spacer.

22. A method of manufacturing a complementary metal-oxide-semiconductor (CMOS) transistor device, comprising:
providing a semiconductor substrate having thereon an NMOS region and a PMOS region;
forming a first and second gate electrodes in the NMOS region and PMOS region respectively;
forming a liner on the sidewalls of the first and second gate electrodes;
forming a silicon nitride spacer on the liner;
ion implanting N type dopants and P type dopants into the semiconductor substrate in the NMOS region and PMOS region respectively, thereby forming a source/drain region;
removing the silicon nitride spacer;
after removing the silicon nitride spacer, forming a silicide layer on the source/drain region;
after forming the silicide layer on the source/drain region, forming a tensile stressed cap layer on the liner and on the silicide layer of the NMOS region, wherein the tensile stressed cap layer directly borders the liner; and
forming a compressive stressed cap layer in the PMOS region.

23. The method of manufacturing a CMOS transistor device according to claim 22 wherein after forming the silicide layer on the source/drain region, the method farther comprises the following step:
forming a tensile stressed cap layer on the liner and on the silicide layer of the NMOS region, wherein the tensile stressed cap layer directly borders the liner; and
forming a compressive stressed cap layer in the PMOS region.

24. The method of manufacturing a CMOS transistor device according to claim 22 wherein both of the tensile stressed cap layer and the compressive stressed cap layer comprise silicon nitride.

25. The method of manufacturing a CMOS transistor device according to claim 22 wherein the liner comprises silicon oxide.

26. The method of manufacturing a CMOS transistor device according to claim 22 farther comprising a step of annealing the source/drain region.

27. The method of manufacturing a CMOS transistor device according to claim 22 wherein the silicide layer comprises CoSi, NiSi, TiSi, PtSi, PdSi or MoSi.

28. The method of manufacturing a CMOS transistor device according to claim 22 wherein the gate electrode comprises polysilicon or metals.

29. The method of manufacturing a CMOS transistor device according to claim 22 wherein the silicon nitride spacer is removed by wet etching method, dry etching method or vapor-etching method.

30. The method of manufacturing a CMOS transistor device according to claim 22 wherein after the formation of the silicon nitride spacer, the method further comprises forming an epitaxial silicon layer next to the silicon nitride spacer.

31. The method of manufacturing a CMOS transistor device according to claim 22 wherein before removing the silicon nitride spacer, the method further comprises the following steps:
recessing the semiconductor substrate to a pre-selected depth to form a recessed area next to the silicon nitride spacer; and
re-filling the recessed area with a semiconductor epitaxial layer.
